(19) United States
(12) Patent Application Publication
(10) Pub. No.: US 2005/0199937 A1
(43) Pub. Date: Sep. 15, 2005

(54) 3D flash EEPROM cell and methods of implementing the same

(76) Inventor: Augustine W. Chang, San Jose, CA (US)

Correspondence Address: SAWYER LAW GROUP LLP, P.O. Box 51418, Palo Alto, CA, 94303, US

(21) Appl. No.: 10/800,257

(22) Filed: Mar. 11, 2004

(51) Int. Cl. H01L 29/76; H01L 29/788; G11C 11/34

(52) U.S. Cl. 257/314; 257/315; 365/185.1

(57) ABSTRACT

A 3 Dimensional EEPROM cell layout, process control, and device model means are proposed. This cell construct uses the pointing shapes of the intrinsic conducting electrodes, thin and high dielectric insulators to customize signal coupling capacitors between intrinsic terminals, and therefore to optimize cell efficiency and operating voltages. Array of the said cells are mixed with high density, low power Schottky-CMOS logic (SCL) gate arrays to implement various array operations. The invented memory-logic device possesses 4F² area per storage unit with 4 multilevel charges, single contact space per logic fan-in or fan-out, and operates with 1.2V supply. We have disclosed our invention with means and control schemes to obtain a compact cell. This cell has properties based on 3D geometrical details including film edge shapes, and composition of insulating materials in the intrinsic electrode constructs.

### FIELD OF THE INVENTION

The present invention relates generally to memories and more particularly to EEPROM cells and methods for implementing such cells.

### BACKGROUND OF THE INVENTION

Electrical erasable and programmable memory EEPROM has emerged as the strongest candidate for implementing SOC level component integration. On the technology front, the practice has been focused on the miniaturization of the physical size of the storage bit, scaling down the cell operating voltages and currents and therefore lowering power consumption, implementing multilevel signal storage, building up on chip apparatus to manage per bit, byte, large and partial arrays, resource sharing schemes to improve array performance, reliability, efficiency and capacity etc.

Wide system applications have been developed in which EEPROMs are ideal memory devices, both as standalone memory parts and as embedded storage units in ASIC. Several attractive features of EEPROMs such as its compactness, low power, and high speed have allowed the making of semiconductor based storage subsystems to replace conventional mechanical and optical disks, controller and microprocessors for network and communications. The name of “FLASH memory and logic device” are adopted for fast operation with large array devices. FLASH devices' commercial value grows with its technological capability and wide product applications. Indeed, a FLASH device is becoming the most compact memory technique, inherently superior to DRAM, and in the present convention it is combined with the low power logic to yield a more generic IC solution for ULSI housing billions of memory bits and millions of logic gates. The current worldwide FLASH device market value is billions of dollars annually and is expanding into a trillion dollar industry in the next decade.

However, like all IC technology and products, the challenges ahead are in the limitations of physical and electrical scale down. Basically, all FLASH cells are analog devices. They require a high voltage supply to operate, such as in the range of 9-12 V. The device speed is much slower than equivalent digital logic parts. The multi-level, dual bit, storage scheme makes it harder to achieve high device capacity as the signal margin requirements are even tougher than those designed for binary storage operations.

Accordingly, what is needed is a system and method for utilizing FLASH cells in a storage environment. The present invention addresses such a need.

### SUMMARY OF THE INVENTION

The present invention provides several embodiments/schemes to lower the cell supply voltage down to 1.2V, and operating current down to sub-microamperes, and to revamp the array peripheral organizations using low power logic circuits. The approach in accordance with the present invention will lead to developing the following:
1. Low power FLASH EEPROM memory products with low power peripherals.
2. FLASH memory arrays as embedded ASIC units with other functional units on the same chip. For example, one possibility comprises mixing with low power logic gate arrays to form field programmable logic gate array (FPGA) devices.

In a further optimization of transistor level construction in a new 3D physical arrangement, the process and flow refinements involve a new circuit configuration that will emphasize or deemphasize certain device physical properties. Several system level logic designs which aim towards the best partitioning of on-chip and off-chip resources in memory, and logics, controlling algorithm among various logic and sub-memory units, are also disclosed.

### BRIEF DESCRIPTION OF THE DRAWINGS

FIG. 1 shows one embodiment of the conventional EEPROM cell circuitry in a system of array core and its supporting peripheral arrangements.

FIGS. 1A and 1B illustrate array circuitry in accordance with the present invention and the 3D view embodiments.

FIGS. 1C-1J are 3D physical layout views of conventional cells.

FIGS. 2A-2E and FIG. 3 show two types of conventional EEPROM cells with two poly-Si layers.

FIGS. 4A and 4B shows respectively the X-Z and Y-Z cross sectional views of the prior art cell.

FIGS. 5A-5C show the depicted cell cross sectional views of the invention array cells.

FIG. 5D is the analytical electrical circuit parameter model corresponding to the prior art and the present invention.

FIGS. 5E and 5F are the cross sectional cell views of the invention in a NAND array embodiment.

FIG. 5G illustrates a prior art DRAM cell structure.

FIG. 5H is Table II, which illustrates calculated device parameters and signal coupling ratios of several EEPROM cell embodiments in the fields.

FIG. 6 shows finished shallow trench isolation (STI) divided cell pockets of the present invention.

FIG. 7 illustrates the floating gate film being deposited along with the sandwiched films and photo-resist coatings.

FIG. 7A-7C show control of the Poly Si floating gate etching slope by forming various arc shapes with respect to the Z-axes.

FIG. 7D illustrates conventional plasma etching advancing from top to bottom with ramping slopes although mostly orthogonal to the targeted Si conducting film in the XY or XZ planes.

FIGS. 8A-8D illustrate that the FG gate sidewalls are wrapped with desirable insulating dielectric layer(s) 550.

FIGS. 9 and 9A-9D show the intermediate steps to form the stacked BL.

FIG. 10 is the finished proximity device profile up to 3 Poly Si layers.

FIGS. 11-12 shows the proximity device profile up to 4 Poly Si layers.

### DETAILED DESCRIPTION

The present invention generally applies to memories and more particularly to EEPROM cells and methods for implementing such cells. The following description is presented to enable one of ordinary skills in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

In the follow sections, device and circuit architectural designs that will yield the most compact physical embodiment of FLASH cells are disclosed. Process flows and treatments are depicted which optimize the 3 dimensional physical constructs of the FLASH cell. An electrical circuit model of the cell is disclosed, and functionality and related processing and reliability issues are also disclosed.

One object of the 3D-model is to closely emulate the electrical parameters of the cell in the sidewall of conducting films. Accordingly, associated capacitance coupling factors are modeled accurately between control gate, floating gate, and source/drain conducting films. As can be seen from compact cell 3D-layout structures, using the state-of-the-art cell dimensions, the Poly WL width and 5D openings are about 0.2 um, the Poly control gate, Poly floating gate, and Poly Bit line conducting film thickness is about 80 to 100 nm, the tunnel oxide thickness is about 10-nm, the vertical insulting dielectric film between the word line and floating gate, and the sidewall insulating film between the floating gate to the Poly Bit can be about 10-1000 nm.

The sub-miniaturization of these critical dimensions becomes more critical as the capacitance parameters between the floating gate and bit line component may have significant impact to the coupling factors and cell efficiency during various cell operating modes. Customization of these dimensions and the shape of the conducting or insulating films will significantly affect the biasing and operating conditions of the cells. It is the object of the present invention to tailor the 3D cell geometries for lowering supply voltages and operating current levels in order to enhance or relax field strengths in certain portion within the cells. This will achieve desirable controls benefiting circuit operations. Specifically, by adjusting the shape of electrodes, size, distance, and dielectric insulating materials, it is possible to:
Increase/decrease the parallel plate capacitor between the wordline (WL) and the floating gate.
Increase/decrease the parallel plate capacitor between the substrate and the floating gate.
Increase/decrease the parallel plate capacitor between the bitline (BL) and the floating gate
Increase/decrease the electric field at certain ridge(s) and/or plane(s) between the WL and the floating gate conducting films.
Increase/decrease the electric field at certain ridge(s) and/or plane(s) between the BL and the floating gate conducting films.

These “proximity effects” impact not only the size of the cell and arrays, but they may also alter the parameter values of certain circuit elements and associated signal coupling within the cell sub-system, therefore significantly influencing cell operating voltages, currents, and biasing conditions, the storage efficiency, and circuit response times. The overall results result in lowering of power consumption, electrical stressing, signal strength or noise margins, reliability, speed, and the device functional yield.

While conventionally the coupling factors involving the sidewall of the insulating film between the floating gate and its surroundings are not addressed, the present invention models the physical and behavior details of the preferred embodiment. In a preferred embodiment, a floating gate is coupled to the Poly bit/source lines with a sidewall capacitance element C2 and C3. Assuming that the WL width is 0.2 um in Y dimension, and runs 0.2 um along the cell in X dimension, its insulating film in the sidewall of the floating gate may be customized from 10 nm to 0.05 um thick and the film dielectric may use SiN with dielectric constant K=7 or SiO2 K=4. By varying the insulation material compositions and the spacing parameter S, the capacitance between the floating gate and word line Cfw=C1 540/541 or 550/575 (thicker) may vary with a wide range from 28x fF to 0.32x fF, where x is defined as the plate capacitance per units of square urn using SiO2 as the dielectric material with spacing of 10 nm.

Likewise, assuming that the vertically stacked BL runs 0.08 um tall in Z dimension, and 0.2 um deep in Y dimension for the cell section, the insulating film may have the thickness of 10 to 50 nm, the dielectric constant can be 7 or 4, so the floating gate to bit line Cfb=C2 may vary from 11.2x fF to 1.28x fF. Therefore, by contemplating K and 1 parameters of the insulating film(s), and the thickness/height of the floating gate and BL, C1/C2 ratios may vary from 22 to 0.03. Accordingly, coupling factors from WL or BL to the floating gate can be adjusted by tailoring suitable C1/C2 ratio and its related film geometries including shapes. For instance, if C1/C2 equals 10, then erasing is highly efficient, but programming is difficult. On the other hand, if C2/C1 is 10, the cell is easier to program.

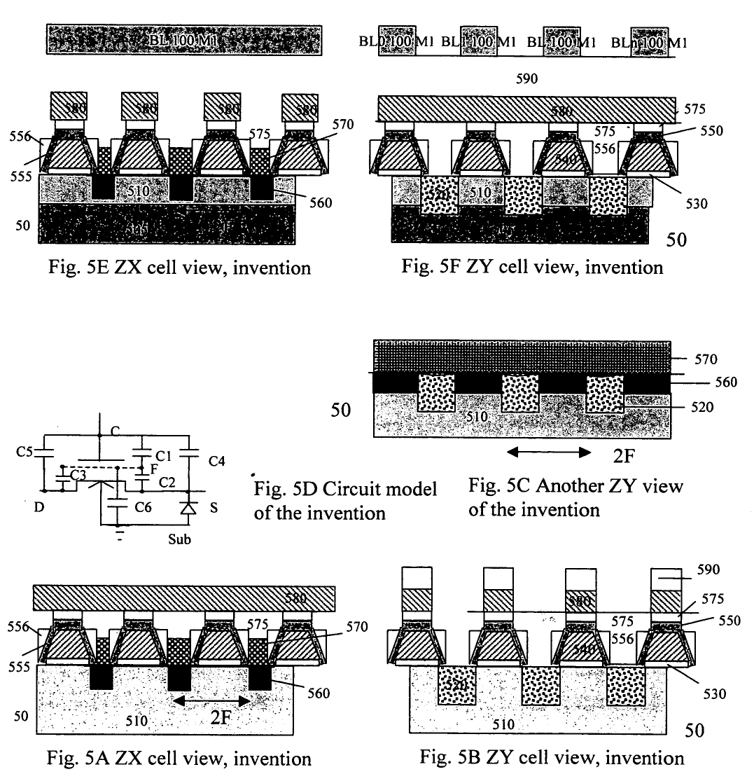

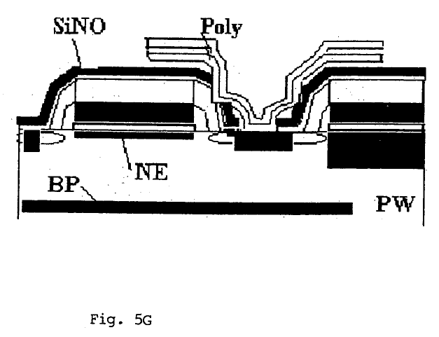

FIG. 5H is Table II which illustrates the calculated device parameters and signal coupling ratios of several prior art EEPROM cell structures. There are 4 cell structures analyzed in the table. Prior art 1 cell represents a design using the stacking gate NAND cell. Prior art 2 cell represents a NOR split gate cell. Both are using 2 poly Si layers. Prior art 3 cell utilizes 4 poly-Si layers with Poly-Si bit lines disposed upward from buried diffusion interfacing with the sidewall of the floating gate. The cell structure in accordance with the present invention emphasizes the shape control of the floating gate conducting stripe and its insulting edges. The C1 and C2 of the intrinsic cell can be manipulated by adjusting the following factors:
1. The thickness of the Floating Gate from 80 to 160 nm.
2. The thickness of the bit-line from 80 to 120 nm.
3. The spacing and composite dielectric constant (K=3-7) of the insulating film between the floating gate and word line disposed above.
4. The spacing and composite dielectric constant of the insulating film between the floating gate and bit line in the neck sidewall direction.
5. The shape of the floating gate conducting electrode. The arc or pointing ridges in specific region(s) along the bit line, and/or a erasing gate.
6. The conductance of the floating gate material.

Accordingly, typical geometry of the embodiments yields different values of capacitors and signal coupling ratios. The statistics shown in table II B-D further detail the signal coupling ratios upon various modes of operations. The cell in accordance with the present invention, taking into accounts of the extremely close spacing between the floating gate and the bit lines, compounded with the curvature or slope of the floating gate sidewall profile resulted from etching rate controls, will add a significant amount of sidewall capacitance to the bit line terminal, so that the floating gate will coupling significant signals from either side of its switching interfaces. The coupling ratios are provided symmetrically around 50%. During the erase operation, when a step pulse switches from the bit line side, too low Fcfb will cause the over erase of electrons.

Accordingly, 50% Fcfb is desirable to retain desirable charge levels. On the other hand, during the writing operation, the floating gate may also obtain significant coupling, ˜50% Fcfc, from the word line side, so it will be easier to attract electrons from the tunnel channel as well as from the hot electron emission at the drain side. All of the prior art devices do not recognize the sidewall effect and the benefits of a custom design. Therefore, in the prior art the coupling ratios were highly asymmetrical, thus caused higher operating voltages to support all modes of cell operations.

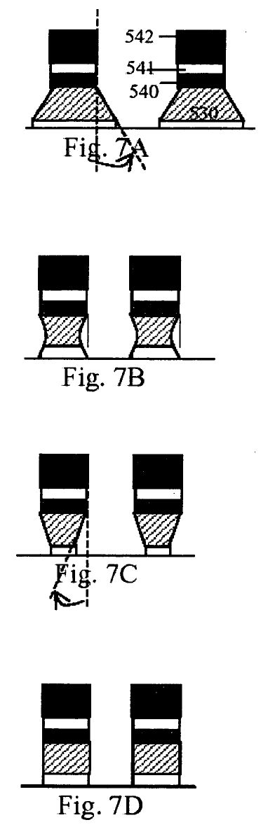

Another feature of the present invention is the control of the shape of the conducting film(s) of the selected gate(s). While the depicted processes will be described later, the concept is briefly illustrated in FIGS. 7-10 where the shapes of the floating gates are controlled during the directional plasma and/or the isotropic chemical etching steps. Referring to FIG. 7, the floating gate film 520, 530 was deposited along with the sandwiched films of Si3N4 540, SiO2 541, and photo-resist coatings (not shown). The gate pattern was developed by selectively opening windows up to the polycrystalline layer film 530. Traditionally, the plasma etching advances from top to bottom with ramping slopes although mostly orthogonal (FIG. 7D) to the targeted Si conducting film in the XY plane, but the etching slope can be controlled with a small angle phi of +−20 degrees, counter clockwise, clockwise, or by forming an arc with respect to the Z-axes as exaggerated in FIGS. 7A-C.

Three proximity effects followed. First, it results in pointing conducting film edge(s), which may cause special electrical field enhancement to help electron emissions at lower applied voltages. Secondly, it creates a slanted surface for the sidewall insulating material (Si3N4 or SiO2). Third, the etching may cause the thinning of insulating layer at the corner of the conducting film. The designer can adjust the size of the coupling capacitors at the signal interface plane(s) with both the effective thickness, and the averaged dielectric constant for a target coupling ratio of the floating-gate to its interface electrode(s), i.e. WL or BL/SL. This customization of Fcxx, the signal capacitive coupling ratio(s), ultimately may determine the efficiency, and biasing requirements of the cell operations.

The Densest Memory and Logic Technology

The preferred embodiments further emphasize the goal toward memory cells and logic gates employing low power, high-speed implementations. Practices are extended from work as disclosed in U.S. Pat. No. 6,590,800. This patent discloses an emerging process known as Schottky-CMOS (SCMOS), which adopted a few variations from conventional CMOS processes. A family of logic macro-cells is disclosed as the Schottky-CMOS-Logic (SCL). A 4T-SRAM core is also disclosed in U.S. Pat. No. 6,590,800. The SCMOS and its cell library offers low power memory and logic constructs that operate at 1.2V supply voltage, sub-microampere dynamic current, with pico-second performance ranges. Besides power savings, the SCL features wide NOR and NAND gating, clocked by duty cycle controlled Giga-Hertz asynchronous pulses. Each logical signal channel takes/requires only a physical chip space of a contact size, and nearly zero capacitance loading.

Combined FLASH cell and low power SCMOS logics form an ideal solution platform for universal IC system integrations. In the near future, the on-chip computing and storage resources will be inter-operative with 1.2 V supply, the memory storage cells offered by present invention, which targeted 4F² cell area per quadratic information storage (dual bit cell), therefore poses ˜8X denser than the DRAM technology. The DRAM cell, as depicted in cell structure which is shown in FIG. 5E, requires a non-shareable storage capacitor and a switch transistor process which stores single bit information taking 4-6F² chip space per bit. The invented EEPROM and SCMOS based gate array logic has the potential to house super large memory sector block (GigaByte) and sub-blocks (1 Byte or nibble) while supporting highest computing power from the low power and high speed million gate asynchronous compact logics with Giga-Hz clocks.

Another application of the present invention is to implement the programmable logic evices PLD using the invention constructs. The prior art of the PLD incorporates 6T-SRAM cells as storage elements for reconfiguration codes and data codes. It uses conventional CMOS-TTL logics as building blocks for computing resources. With the present invention, PLD is conceivably implemental by using our 3D-EEPROM cell, 4T-SRAM cells, and the logics are delivered by the highly area and power efficient SBD diode trees, CMOS inverters, and pass transistors. This super PLD will feature as the most efficient field programmable devices to support the highest capacity IC solutions with ideal hardware and software capabilities. To describe the features of the present invention in more detail, refer now to the following discussion in conjunction with the accompanying figures.

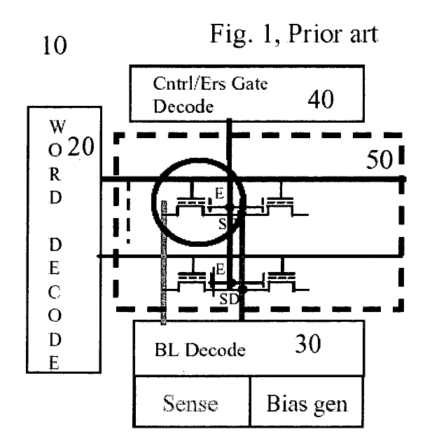

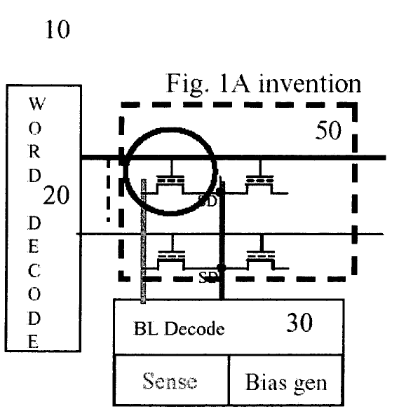

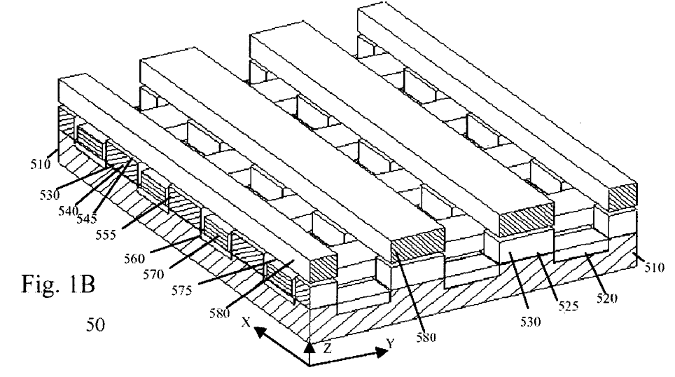

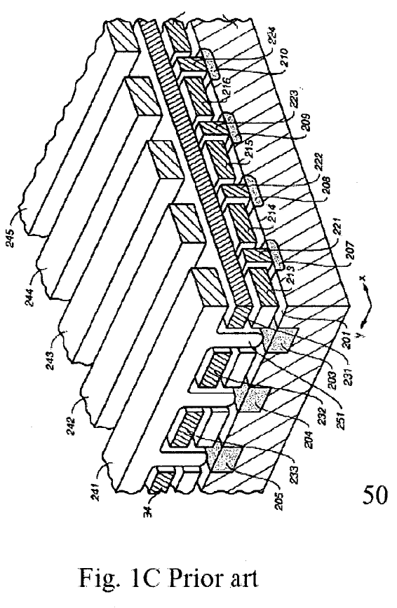

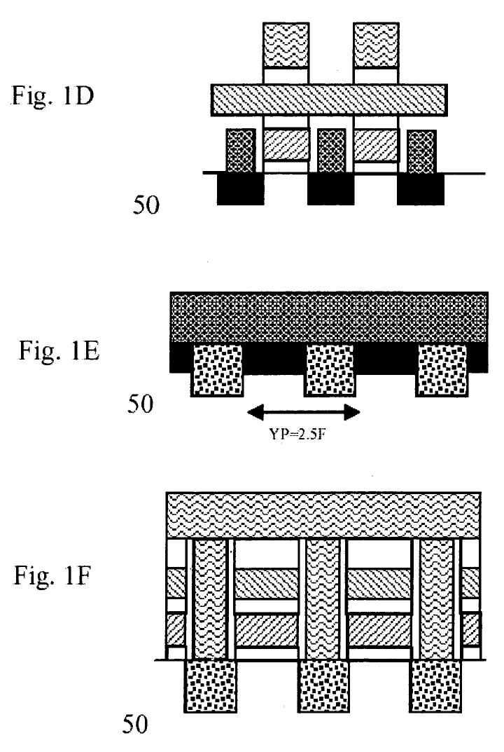

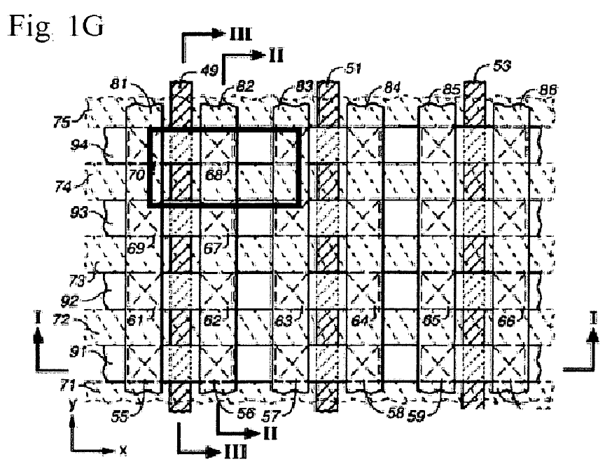

FIG. 1 shows one embodiment of the prior art EEPROM cell circuitry 50 in a system of array core and its supporting peripheral arrangements 10. In this embodiment, the cell employs 4 layers of Poly-Si layers, but the cell size is highly compact because it shares source drain electrodes and contacts with its adjacent members. The cell area approaches 4˜5F² per storage element. Memory array cells 50 are represented by the 4-terminal transistor circuit symbols; the control gate, source and drain terminals, and an erase gate. The common substrate contact(s) are omitted for discussion until necessary for purposes of simplicity.

The 3D physical layout views are shown in FIGS. 1C-1F. The arrays cells are operated by its surrounding circuitries sharing the same substrate 10 in a common substrate bulk. Typically, they are the word 20 and bit-decode circuitry 30, and other specific controls such as erasing 40, programming, inhibiting, multiplexing, and reading to support various operation modes.

Standalone IC parts can be made from mainly arrays of the EEPROM cells or by using them as embedded units to mix with other types of logical and or analog circuits to implement certain specific applications, therefore called programmable logic device (PLD) or application specific integrated circuit (ASIC). In the sections which follow, the state of the arts for techniques of customizing the construction of the array cells, to achieve a better circuit density, lowering operating voltages, current levels and power consumptions, and improving the reliability will be discussed. The issues of mixing the arrays with other circuit constructs, firmware and algorithms therefore to explore efficient and useful applications are also discussed.

Density, Process, and Operating Voltage Improvements

The prior art requires 4 poly-Si layers, besides other metal layers, to wire the 4 electrodes for various array circuit operations. The cell horizontal area is compact compared with other prior art as shown in FIGS. 1H through 1J, from a structural viewpoint. From FIG. 1D and FIG. 1E, it can be seen that the X and Y pitches are 2 and 2.5 minimum feature sizes respectively. If it is assumed that they are 200 nm, then the cell size is about 5 F² or 2 k sqnm per bit. By applying the specific means of controls taught by present invention, the poly layer 4 may be saved and the erasing gate and its associated control circuitry can be eliminated. More efficient cell and array operations will stem from shaping the intrinsic cell electrodes in layout details and employing process controls from physical implementations. The operating voltages are reduced to 5V among cell electrodes, the shape and height of the floating gate are customized, and the dielectric materials and spacing of certain insulting layer(s) among interfacing control, floating, and source/drain conducting stripes are changed.

FIGS. 1A and 1B illustrate array circuitry in accordance with the present invention and the 3D view embodiments. The erasing gate and its control circuitry are eliminated, and the poly 4 films are saved from cell layout. The cell area now becomes 4F². FIGS. 5A-5C show the depicted cell cross sectional views of the NOR array cells 50. FIGS. 5E and 5F illustrate a NAND array cell. FIG. 5D depicts the circuit schematic of the intrinsic cell elements. The detail constructs and its process flow are explained later. Basically, from the cell behavioral viewpoint, the cell is comprised of a 4 terminal transistor with 5 electrodes; control gate, floating gate, source, drain, and back gate. The inter and intra circuit interfaces are controllable via 4 external terminals, with the 5th terminal (Floating gate) controls governed by design via the signal coupling ratios of each circuit operations.

Charge storage operations are quantified by the Vt value(s) (binary and/or multi-levels) of the transistor as the results of various cell operations. The charge transport mechanisms of the cell are governed by the device parasitic parameters, mainly the 6 capacitors and the back-gate junction diode. Specifically, the effective plate areas, shape of the conducting stripes, the dielectric constant, and spacing of insulating materials determine the value of the intrinsic capacitors. The electrical coupling effects among the 3 interface electrodes and the floating gates, can be accurately modeled and verified with external biasing voltages and transient waveforms, which are defined as operating conditions.

The development of multiple level storage cells greatly enhances bit density and device capacity attributes of the EEPROM cells but unfortunately further complicates the issues of signal noise margins and the separation of digitization, range of operating voltages and its implication on chip high voltage data processing and inhibition controls. Therefore, it is a challenge to develop methods of design and provide means of process controls for better cell efficiency that involve both the single bit and the multi-bit storage cells.

Circuit Configuration, Process Sequences, and Mode of Operations

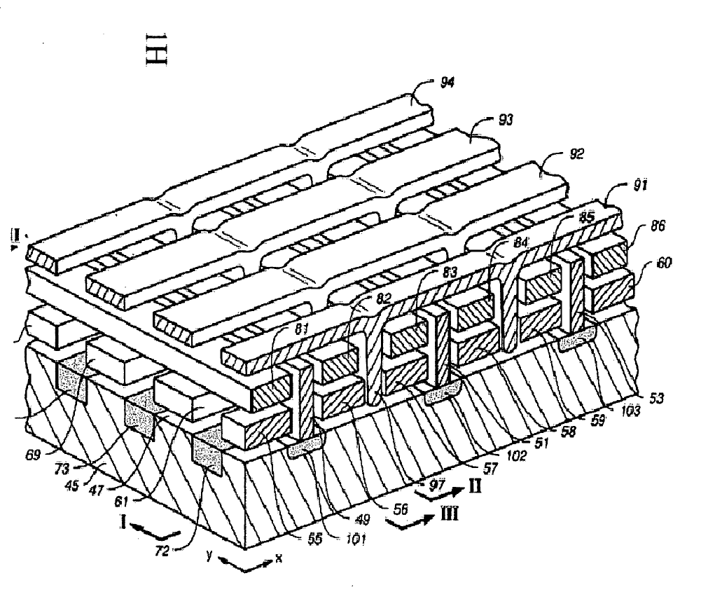

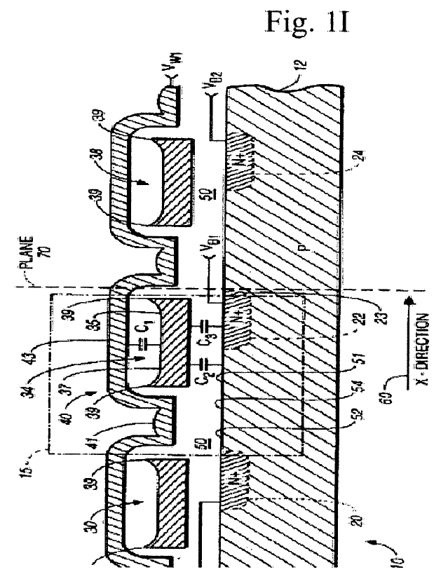

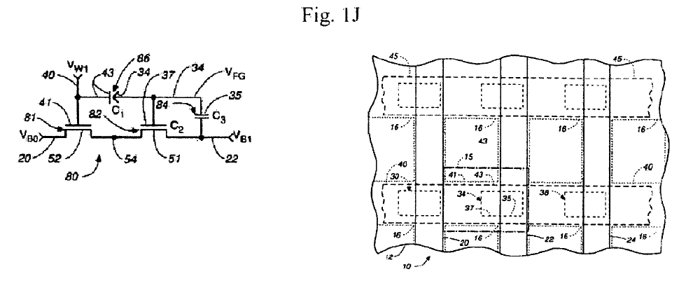

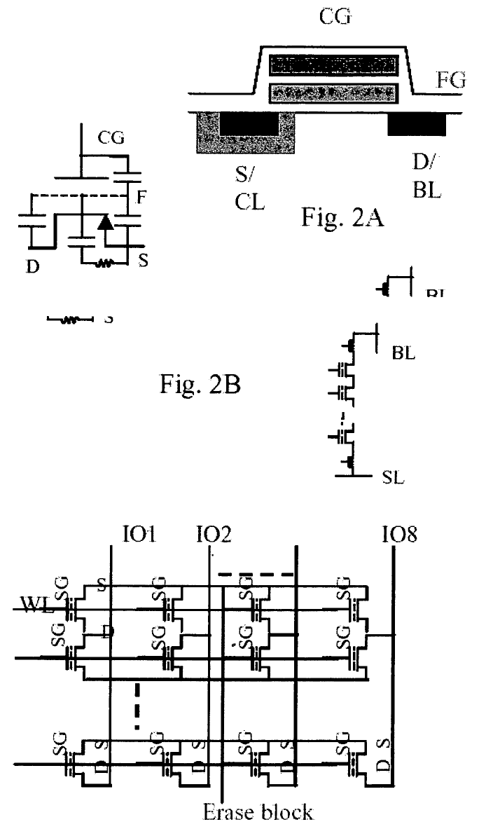

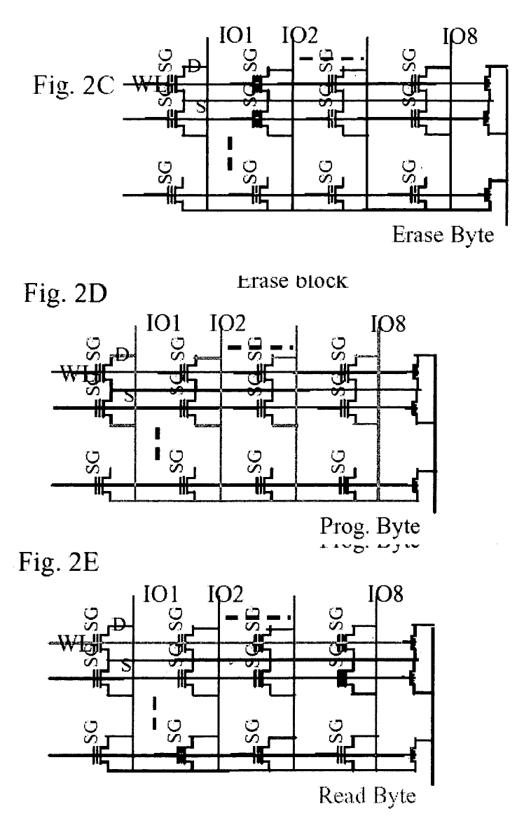

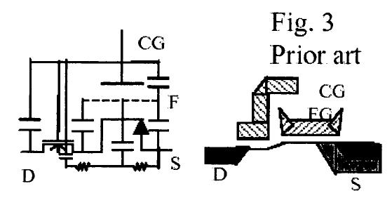

The cell constructs and their modes of operations are reviewed for several conventional embodiments. FIGS. 2A-2E and FIG. 3 illustrate two types of conventional EEPROM cells with two poly-Si layers. FIG. 2B illustrates the array embodiment of NAND plane cells. The array has the compact area because in logical sense, string of cells can be stacked by a NANDing configuration, where multiple storage transistors are connected in a serial chain so the total array size is at the minimum for saving of the inter-cell contacts in its physical implementations. The drawback is that it confines the cells in a string, and they are operated in current mode, and the speed may be extremely slow due to high RC time constant for the stacking cells. Table I shows operating conditions of the cell for erase, write, and read modes. The cell requires 12 V+(some vendors report ˜20V for multiple-level storage cells) supply voltage to support generic operations.

As before mentioned, FIG. 2A and FIG. 3 illustrate two other conventional embodiments. The cell employs two layers of poly-Si layer using split gate for control and floating gates. The main drawback is larger cell size. However, it can be bit-wisely operated in voltage mode. The operating voltages are lower, the speed is better for a NORing logical array configuration, and may have sidewall coupling effects due to the split-gate arrangement.

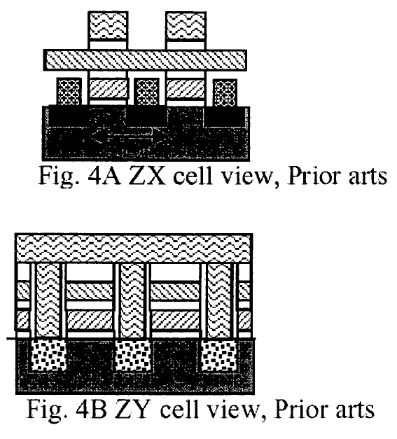

The prior art shown in FIGS. 4A and 4B shows a cell configuration using coupling capacitors from the side neck regions of the floating gate conducting film. The cells are constructed from four (prior art) or three (the present invention) polycrystalline films and other metal wiring infrastructures. FIG. 4A shows the X-Z and Y-Z cross sectional views of the cell. FIGURE. 5C shows another view of the cell in a different Y-Z plane. FIG. 5D is the analytical electrical circuit parameter model corresponding to the prior art and the present invention. The main process steps of the Si-bulk and thin film process sequences and process flow are reviewed below:

Main Process Flows

1. STI Process Sequence, Prior Arts
   1. Starts with P- substrate or P- well˜1e15 atoms/cm3.
   2. Si/SiO2/Si3N4 sandwich.
   3. Open Iso trench windows.
   4. RIE trench, ˜200 nm wide 400 nm deep.
   5. Thermal SiO2˜20 nm.
   6. Over fill trench with Si3N4 or phosphoric silicate glass PSG.
   7. Plasma etch back.
   8. Mechanical polishing.
2. FG/T1, S/D Diffusion, BL/T2 Invention
   1. SiO2 10 nm
   2. Vt implants, SiO2 removal
   3. Gox 1 grow ˜10 nm
   4. Poly 1-FG/T1, As doped 1e15˜1e16, 80 nm, Shape control*Note 1
   5. ONO grow, 5-10-5 nm
   6. SiO2+PR mask, FG/T1 pattern ˜0.2 um,
   7. Neck CVD Si3N4, 10-50 nm
   8. BL diffusion Implant. Remove floor nitride, SiO2 at BL pattern.
   9. Thermal SiO2 Gox2˜12 nm for T2, S/D N+Implant.
   10. Plasma etch back.SiN/SiO2
   11. Doped Poly 2, BL/T2 formation, Si etch back
   12. S/D Diffusion N++Implant,
   13. LPO fill, FSG, etch back
3. Poly 3, WL Definition, 100 nm Thick Conventional Means
   1. Uses ono layers as dielectric thin film
   2. Customized spacing for C1/C2 ratios
4. Poly 4 Erase Gate Definition, 100 nm Thick Prior Arts
   This step may be saved

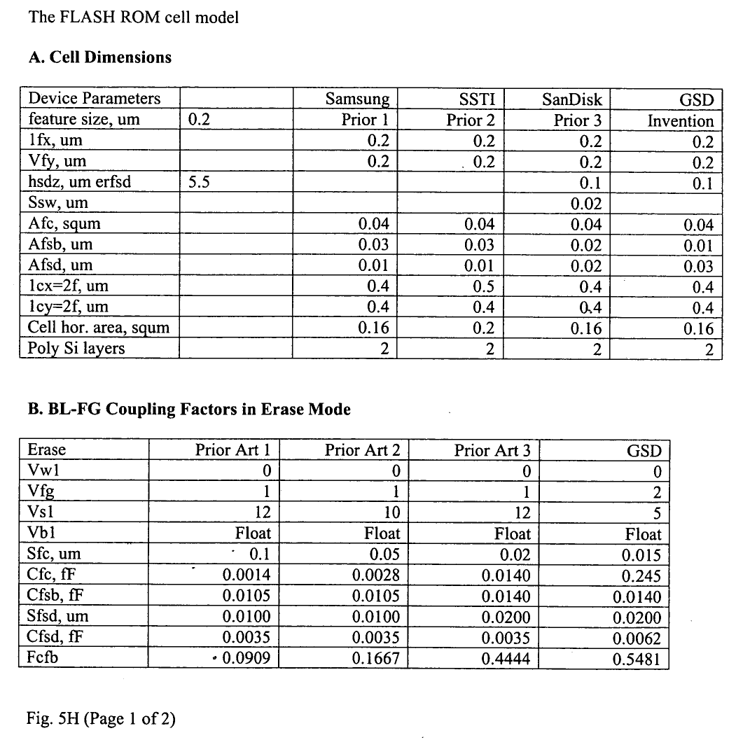

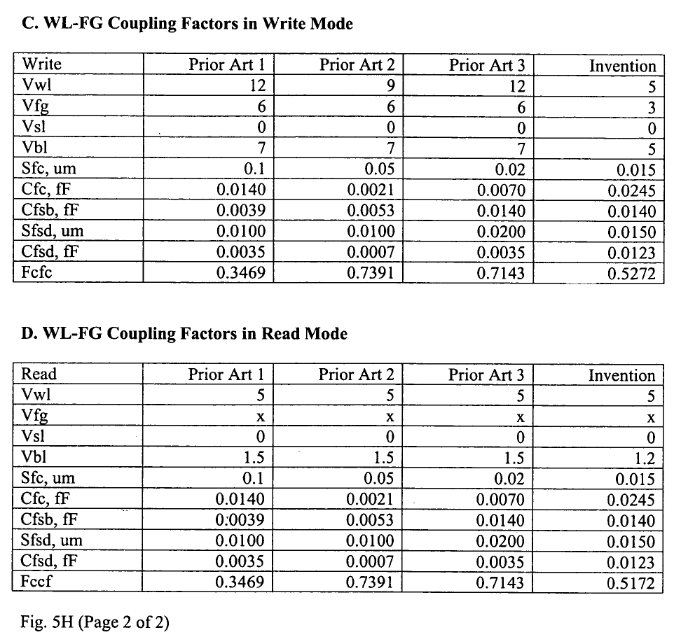

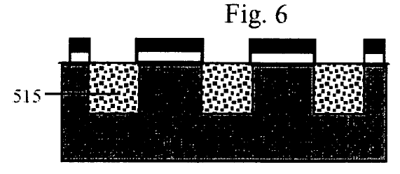

For those skilled in the state of art in CMOS device isolation and transistor technology, typical process specifications using the recessed oxide isolation (ROI) or shallow trench isolation (STOI) steps to achieve inter-cell full or partial isolations are utilized. The preferred embodiment is to form STOI 520 in the P- type substrate 510 with minimum width of 200 nm, and depth of 400 nm. Chemical etching and mechanical polishing (CMP) is performed mainly to make a flat surface for later complicated metal wiring needs. The STOI will form trenches 520 dividing the substrate 510 along the X-axes. FIG. 6, and bulk region profiles shown in FIG. 4A, FIG. 4B, and FIG. 5C shows finished STOI divided cell pockets. Prior to the PSG landfill, Boron implant (not shown) may be performed in the bottom of the trench to insure device isolations.

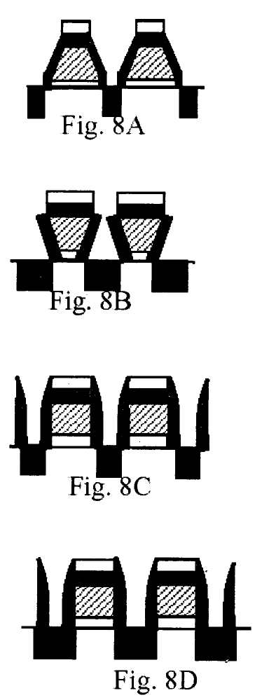

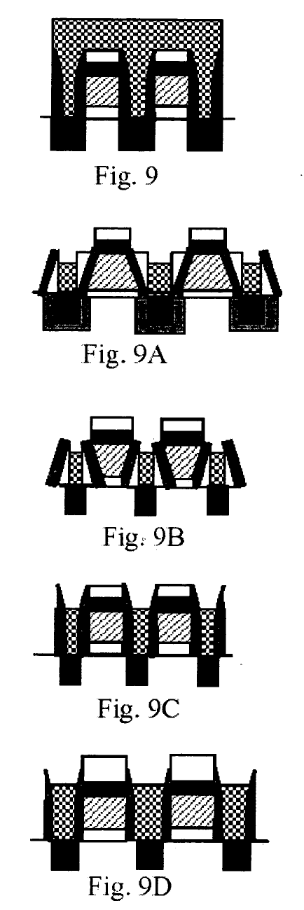

Referring now to FIG. 5A and FIG. 7A, 10 nm tunnel oxide film 520 is re-grown and disposed above it with 80˜160 nm thick with doped Poly-Si layer1 530, Si3N4 and SiO2 layers 540, 541, and photo-resist layer 542 to pattern floating gate islands in the array region. The floating gate etching is performed as shown in typical cross sectional profile sequences shown in FIG. 7A-D, FIG. 8A-D, and FIG. 9, FIG. 9A-D. In one of the depicted embodiments, the floating gate (FG) conducting film has thickness about 100 nm. Then FG etching 1 is performed, the SiN, SiO2, photo-resist films masked the very top layer, and directional plasma etching atoms would remove the exposed films mostly orthogonal to the Z-axes. The etching rate and slopes are controlled such that the film may end up in several desirable shapes as shown in FIGS. 7A-7D. In FIGURE 7A, the angle is clockwise about 10-20 degree, the film shape is convex. In FIGS. 7B and 7C, the film shape is concave arc or forms a clockwise angle. In FIG. 7D, the neck region forms straight vertical edges. Whatever shapes are utilized for the FG electrode depends on the desirable capacitor coupling ratios (C1/C2), and field strengthen effect at certain ridges which will be made or intend to make that will comprehensively benefit in lowering cell operating voltages.

FIGS. 8A-8D illustrate that the FG gate sidewalls are wrapped with desirable insulating dielectric layer(s) 550. Followed with SiO2 refill 555, they are selectively etched down with the BL patterns. These insulating films and resulted capacitors are critical and relatively to other parasitic capacitors of the FG, should it be WL, Erase Gate, or channel capacitor, to determine close or loose coupling factors among BL 570, WL 580, and FG 530. The gap is implanted with self-aligned N++/N− diffusions 560. The source drain diffusion has options to form graded PN junction FIG. 9A, or abrupt FIG. 8A-8D as required by various cell embodiments.

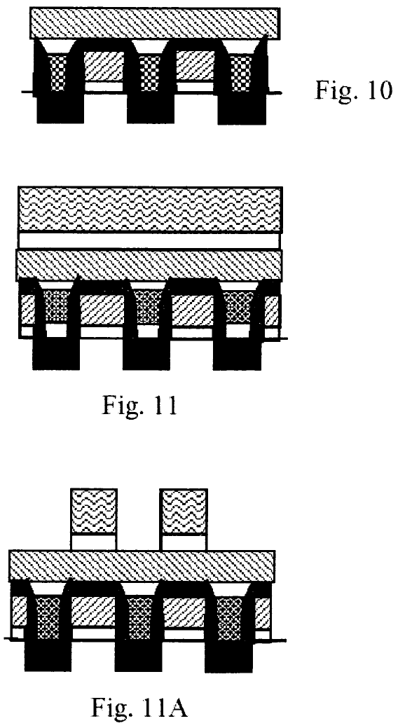

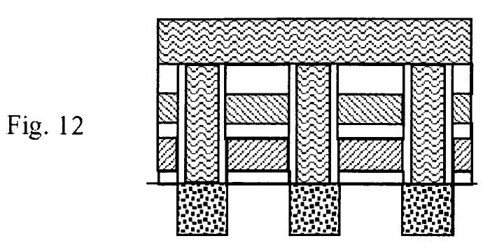

FIGS. 9, 9A-9D show the intermediate steps to form the stacked BL. In FIG. 9, doped Poly-Si2 layer is disposed that will fill the gap of the sidewalls. Etch back will control the BL height, and the final interface area(s) between the BL and FG electrodes. The BL height also determines the distance between BL and WL, which we intend to minimize cross coupling. FIGS. 9A, 9B, and 9C show three examples of the resulted FG/BL electrodes. FIG. 9D shows that the distance of FG to WL spacing also provides signal isolation gap between BL and WL. The insulating film 540, 541 between the local WL 580 and FG 530 determines C1 value and field strength during various cell operations. It is the intention to adjust the composition and distance to yield desirable C1 in relation to C2 and channel capacitances. The embodiment of WL films is rather straightforward. The gap above BL 570 is filled and leveled off with low K=3 FSG, then dispose ˜100 nm thick doped Poly-Si3 layer. It is then etched out with WL patterns. The post thin film metal processes are conventional. FIG. 10 is the finished proximity device profile up to 3 Poly Si layers. FIG. 11 shows the proximity device profile up to 4 Poly Si layers. For the preferred embodiment, these steps are saved.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A FLASH array comprising:
a plurality of FLASH cells, each FLASH cell comprising a three-dimensional layout structure where sidewall, top and bottom surfaces of a floating gate include insulating and conducting films such that electrical parameters of an element of the FLASH cell can be accurately modeled and controlled.

2. The FLASH cell of claim 1 wherein the associated capacitive coupling factors are modeled accurately between a control gate, a floating gate and the conducting films.

3. The FLASH cell of claim 2 wherein the charge storage may be quantized by multiple threshold levels.

4. The FLASH cell of claim 2 wherein the physical layout of electrodes are based on proximity effects for the dimensional and shape customizations.

5. The FLASH cell of claim 2 wherein the proximity effects provide for the balanced control-to-floating-gate to bit-line-to-floating-gate capacitance ratios for all cell operation modes.

6. The FLASH cell of claim 2 wherein the proximity effects lead to lower voltage array operations, power, delay, and stressing advantages.

7. The FLASH cell of claim 2 wherein the proximity effects result in array compact sizes.

8. The FLASH cell of claim 2 wherein the proximity effects provide for device yield and cost advantages.

9. The FLASH arrays of claim 1 which includes a SCL circuit for low power logic peripherals and controls.

10. The FLASH arrays of claim 1 which include SCL peripheral circuitry that utilize 4T SRAMs.

11. The FLASH cell of claim 2 which includes SCL peripheral circuitry to form PLD/FPGA.

12. The FLASH cell of claim 2 which includes SCL peripheral circuitry to provide for use with hardwired or software macros.

13. A method of fabricating a FLASH cell comprising the steps of:
forming a plurality of a shallow trenches in a substrate;
forming tunnel oxide film above trenches;
etching at least one gate profile in association with the desirable capacitance coupling ratios;
providing a bit line film and word line film in accordance with desirable capacitance coupling ratios.

14. The method of claim 13 providing the physical layout of electrodes based upon proximity effects for the dimensional and shape customizer.

15. The method of claim 13 wherein the proximity effects provide for the balanced control-to-floating-gate to bit-line-to-floating-gate capacitance ratios for all cell operation modes.

16. The method of claim 13 wherein the proximity effects lead to lower voltage array operations, power, delay, and stressing advantages.

17. The method of claim 13 wherein the proximity effects result in array compact sizes.

18. The method of claim 13 wherein the proximity effects provide for device yield and cost advantages.
